(19) United States
(12) Patent Application Publication
(10) Pub. No.: US 2015/0221773 A1
(43) Pub. Date: Aug. 6, 2015

(54) SEMICONDUCTOR DEVICE AND METHOD FOR PRODUCING SAME

(71) Applicant: Sharp Kabushiki Kaisha, Osaka-shi, Osaka (JP)

(72) Inventor: Yasuhiro Yokoi, Osaka-shi (JP)

(21) Appl. No.: 14/425,735

(22) PCT Filed: Aug. 30, 2013
(86) PCT No.: PCT/JP2013/073299

§ 371 Date: Mar. 4, 2015

(30) Foreign Application Priority Data
Sep. 5, 2012 (JP) 2012-194973

(51) Int. Cl. H01L 29/786; H01L 21/441; H01L 29/66; H01L 21/02; H01L 29/24; H01L 27/12

(52) U.S. Cl. CPC H01L 29/7869; H01L 29/24; H01L 29/78633; H01L 27/1225; H01L 27/124; H01L 27/1248; H01L 27/1288; H01L 29/66969; H01L 21/02565; H01L 21/441

(57) ABSTRACT

This semiconductor device (100A) includes a plurality of lines (7(m), 14(n)), a thin-film transistor (10) including a semiconductor layer as its active layer, a pixel electrode (3(m)), a protective layer (8) covering the thin-film transistor (10), an auxiliary line (9(m)) arranged on the protective layer (8), and a common electrode (11) which overlaps with at least a portion of the pixel electrode (3(m)) with the protective layer (8) interposed and which is electrically connected to the auxiliary line (9(m)). The auxiliary line (9(m)) is arranged over one line (7(m)). The auxiliary line (9(m)) has a lower electrical resistance than the common electrode (11). When viewed along a normal to a substrate, the auxiliary line (9(m)) runs along the one line (7(m)). And when viewed along a normal to the substrate, the common electrode (11) has an opening area (11u(m)) which overlaps at least partially with the one line (7(m)).

### TECHNICAL FIELD

The present invention relates to a semiconductor device and a method for fabricating such a device, and more particularly relates to an active-matrix substrate for use in a liquid crystal display device or an organic EL display device and a method for fabricating such a substrate. In this description, the “semiconductor devices” include an active-matrix substrate and a display device which uses the active-matrix substrate.

### BACKGROUND ART

An active-matrix substrate for use in a liquid crystal display device and other devices includes switching elements such as thin-film transistors (which will be hereinafter referred to as “TFTs”), each of which is provided for an associated one of pixels. Such an active-matrix substrate including TFTs as switching elements is called a “TFT substrate”.

As for TFTs, a TFT which uses an amorphous silicon film as its active layer (and will be hereinafter referred to as an “amorphous silicon TFT”) and a TFT which uses a polysilicon film as its active layer (and will be hereinafter referred to as a “polysilicon TFT”) have been used extensively (see Patent Document No. 1, for example). Recently, people have proposed that an oxide semiconductor be used as a material for the active layer of a TFT instead of amorphous silicon or polysilicon. Such a TFT will be hereinafter referred to as an “oxide semiconductor TFT”. Since an oxide semiconductor has higher mobility than amorphous silicon, the oxide semiconductor TFT can operate at higher speeds than an amorphous silicon TFT. Also, such an oxide semiconductor film can be formed by a simpler process than a polysilicon film.

Patent Document No. 1 discloses a liquid crystal display device which drives its liquid crystal layer by the lateral electric field method. In the liquid crystal display device disclosed in Patent Document No. 1, a counter electrode which faces pixel electrodes is arranged to cover drain signal lines (source lines) with an insulating layer interposed between them.

### CITATION LIST

### Patent Literature

Patent Document No. 1: Japanese Laid-Open Patent Publication No. 2011-48394

### SUMMARY OF INVENTION

### Technical Problem

In the liquid crystal display device disclosed in Patent Document No. 1, the counter electrode is arranged to cover the drain signal lines with an insulating layer interposed between them. That is why if the thickness of the insulating layer is insufficient, the parasitic capacitance produced between the counter electrode and drain signal lines would sometimes increase so much as to debase the display quality of the liquid crystal display device.

Thus, a primary object of the present invention is to provide a semiconductor device which can minimize a decline in display quality and a method for fabricating such a device.

### Solution to Problem

A semiconductor device according to an embodiment of the present invention includes: a substrate; a plurality of lines; a thin-film transistor including a semiconductor layer as its active layer; a pixel electrode; a protective layer covering the thin-film transistor; an auxiliary line arranged on the protective layer; and a common electrode which overlaps with at least a portion of the pixel electrode with the protective layer interposed between them and which is electrically connected to the auxiliary line. The lines, transistor, pixel electrode, protective layer, auxiliary line and common electrode have all been assembled together on the substrate. The auxiliary line is arranged over an arbitrary one of the plurality of lines. The auxiliary line has a lower electrical resistance than the common electrode. When viewed along a normal to the substrate, the auxiliary line runs along the arbitrary one of the lines. And when viewed along a normal to the substrate, the common electrode has a first opening area which overlaps at least partially with the arbitrary one of the lines.

In one embodiment, the auxiliary line has light shielding property.

In one embodiment, the semiconductor device further includes an insulating layer formed over the common electrode, and the pixel electrode formed on the insulating layer.

In one embodiment, the pixel electrode has a second opening area which overlaps at least partially with the arbitrary one of the lines.

In one embodiment, the semiconductor layer is an oxide semiconductor layer.

In one embodiment, the oxide semiconductor layer includes In, Ga and Zn.

In one embodiment, the oxide semiconductor layer is a crystalline In—Ga—Zn—O based semiconductor layer.

A method for fabricating a semiconductor device according to an embodiment of the present invention includes the steps of: (a) providing a substrate; (b) forming a plurality of lines and a thin-film transistor on the substrate, the thin-film transistor including a semiconductor layer as its active layer; (c) forming a protective layer that covers the thin-film transistor; (d) forming a first conductive film on the protective layer and forming a second conductive film on the first conductive film, the second conductive film having a lower electrical resistance than the first conductive film; and (e) patterning the first and second conductive films through a single photomask by half-tone exposure process, thereby forming, out of the first conductive film, a common electrode which has an opening area that overlaps at least partially with an arbitrary one of the plurality of lines and also forming, out of the second conductive film, an auxiliary line which runs along the arbitrary one of the lines.

In one embodiment, the step (b) includes the step (b1) of forming a pixel electrode on the substrate, and the step (e) includes the step (e1) of forming the common electrode so that the common electrode overlaps with the pixel electrode with the protective layer interposed between them.

In one embodiment, the method further includes the steps of: (f) forming an insulating layer over the auxiliary line, and (g) forming a pixel electrode which overlaps with the common electrode with the insulating layer interposed between them.

In one embodiment, the semiconductor layer is an oxide semiconductor.

In one embodiment, the oxide semiconductor layer includes In, Ga and Zn.

In one embodiment, the oxide semiconductor layer is a crystalline In—Ga—Zn—O based semiconductor layer.

### Advantageous Effects of Invention

Embodiments of the present invention provide a semiconductor device which can minimize a decline in display quality and a method for fabricating such a device.

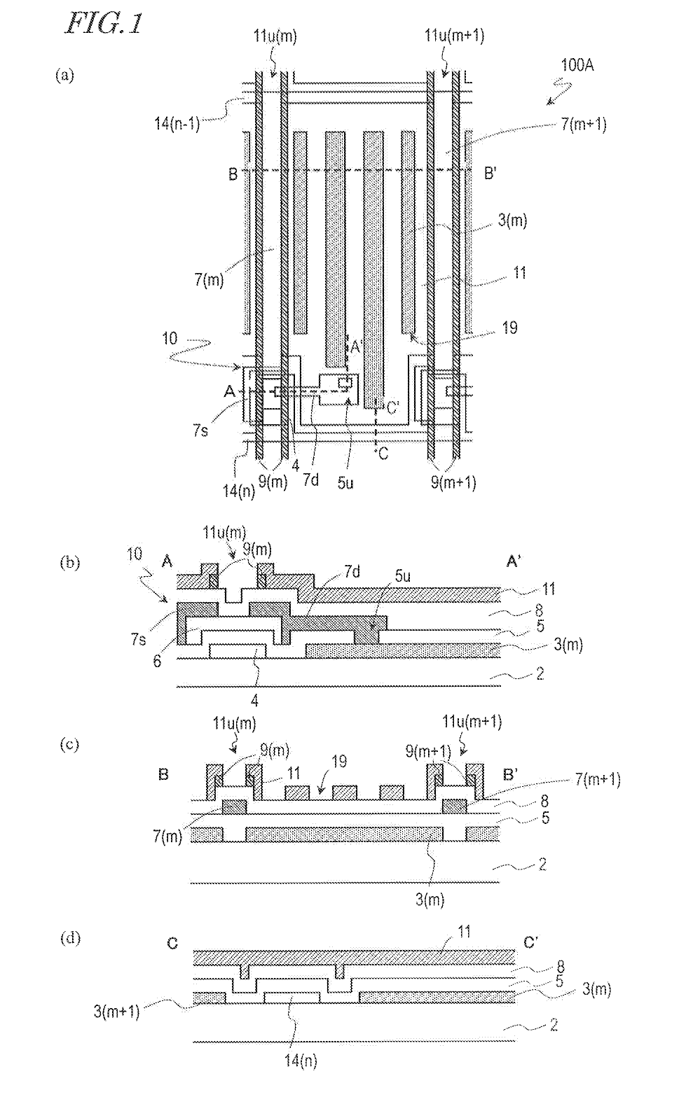

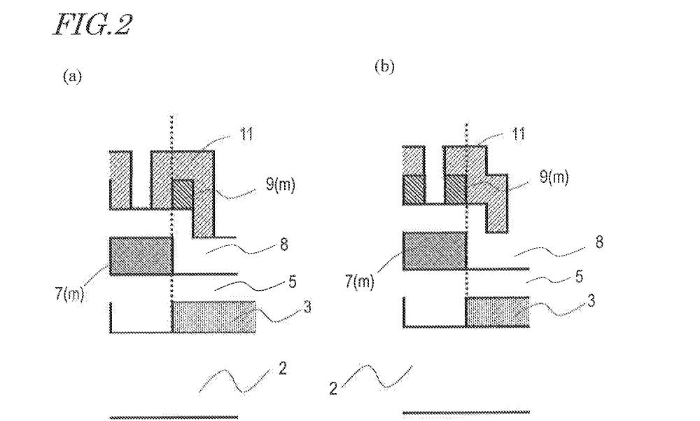

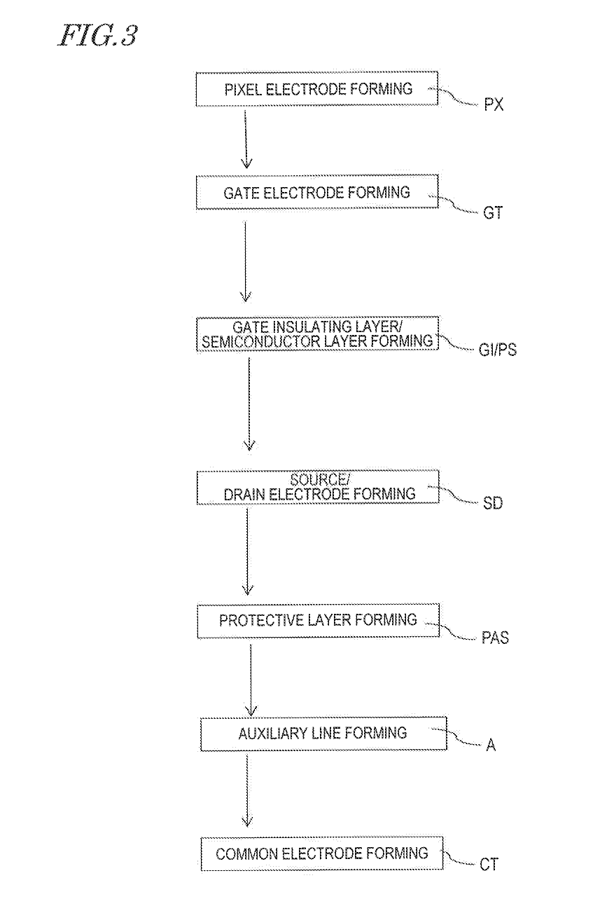

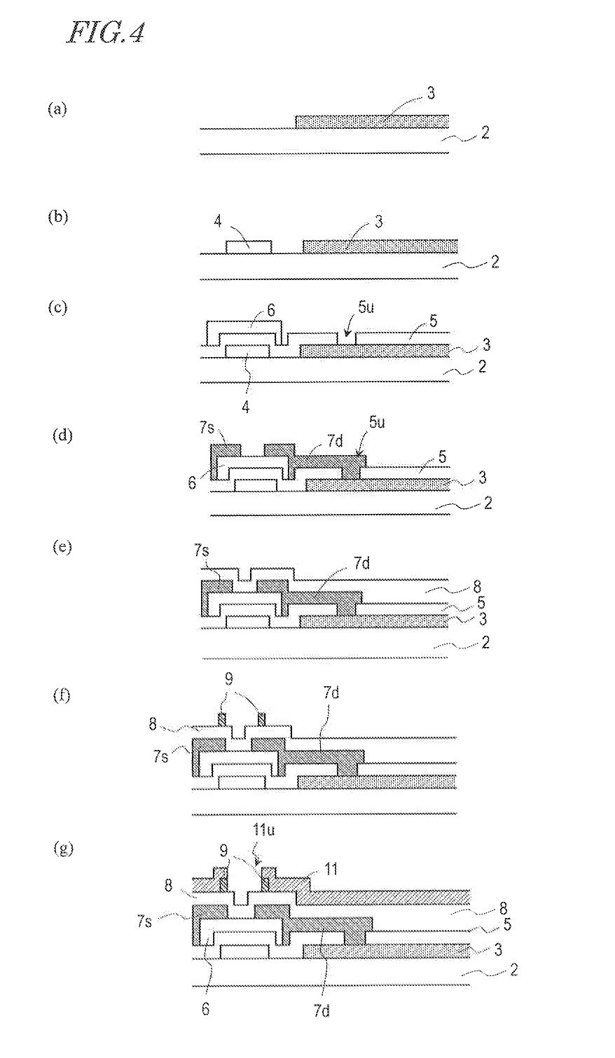

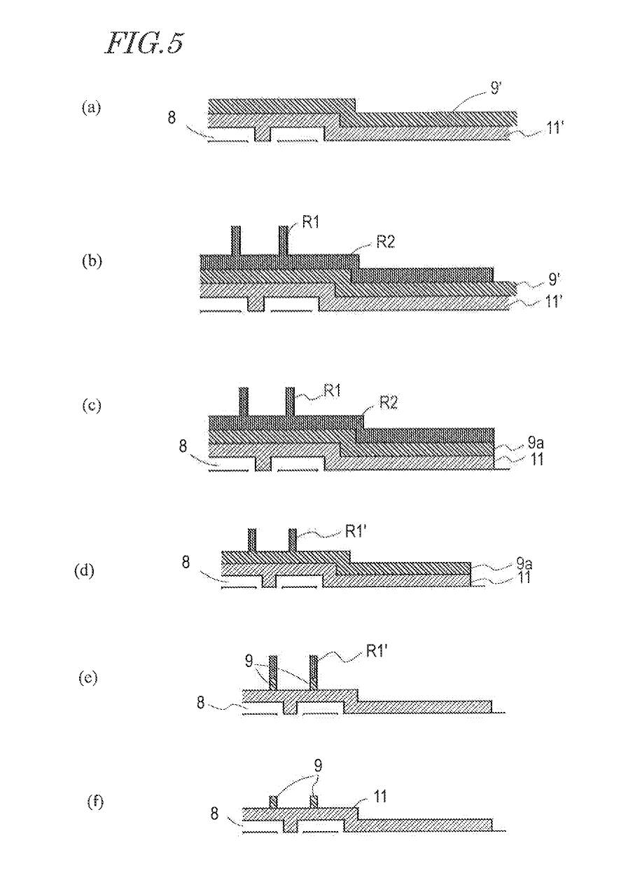

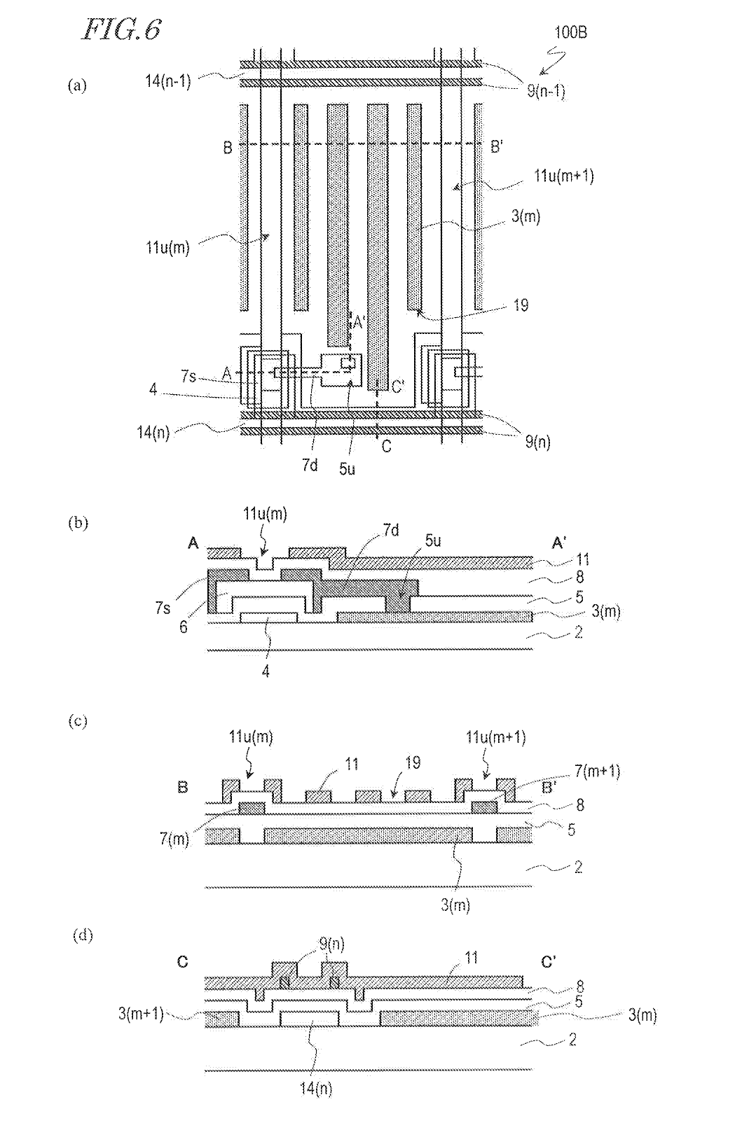

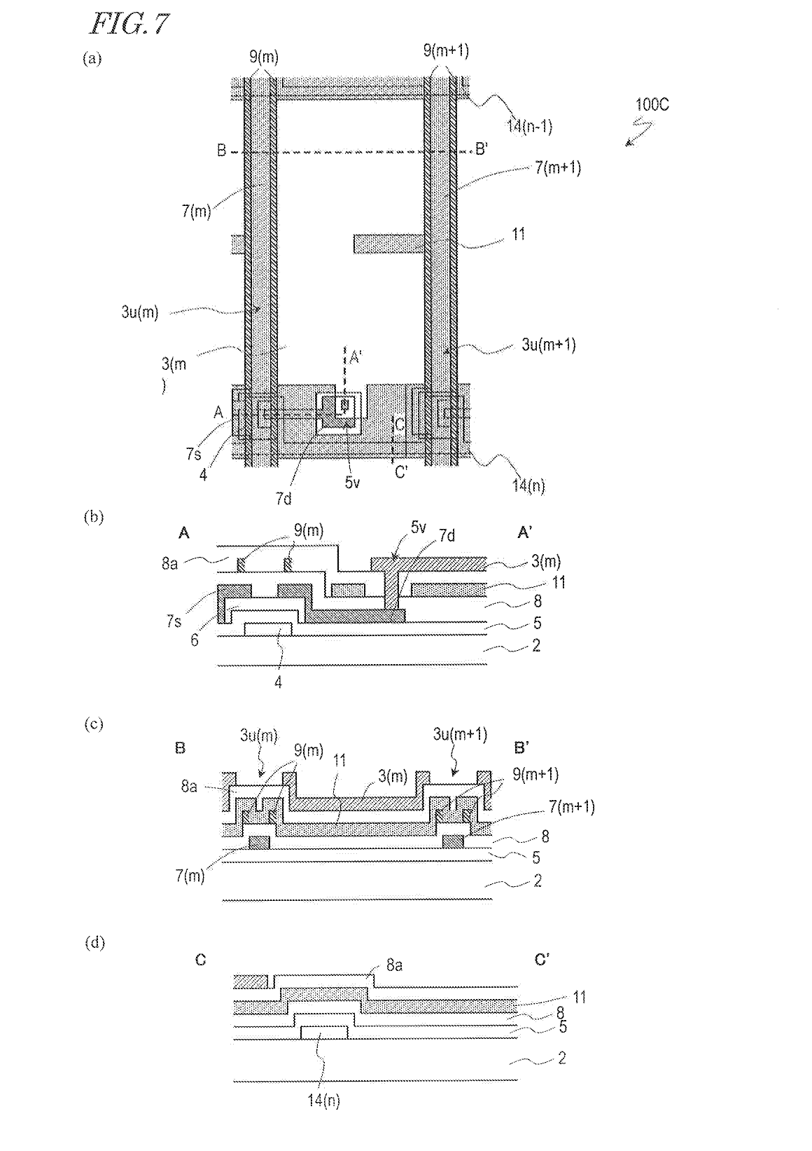

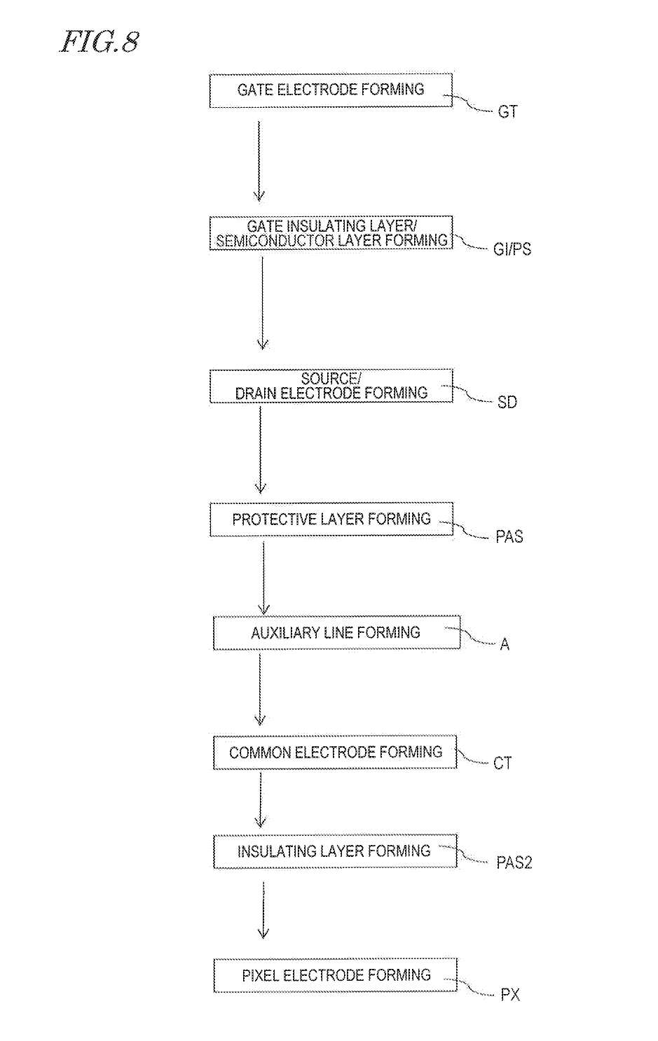

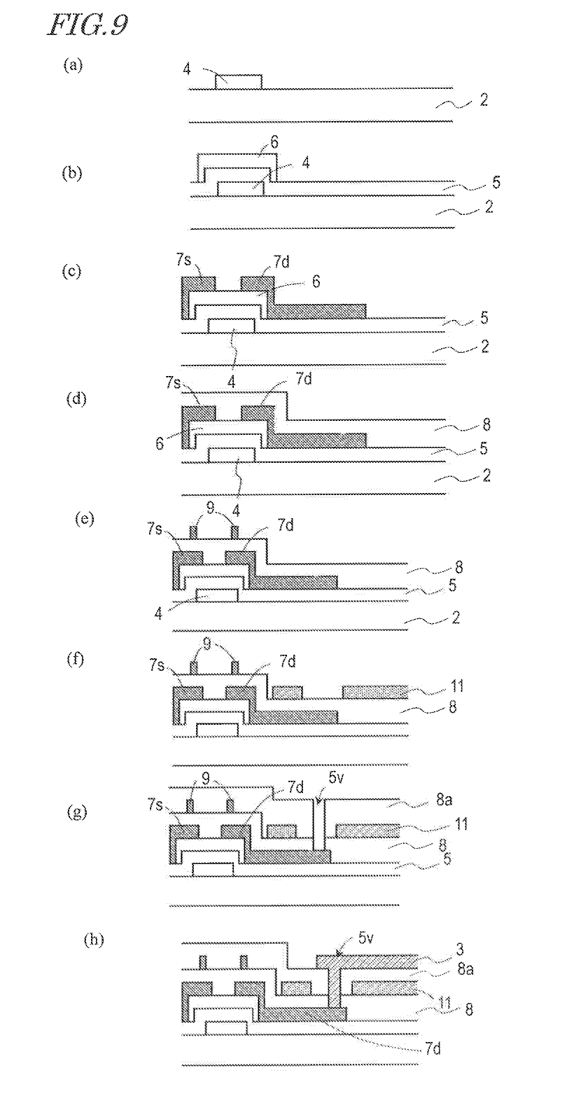

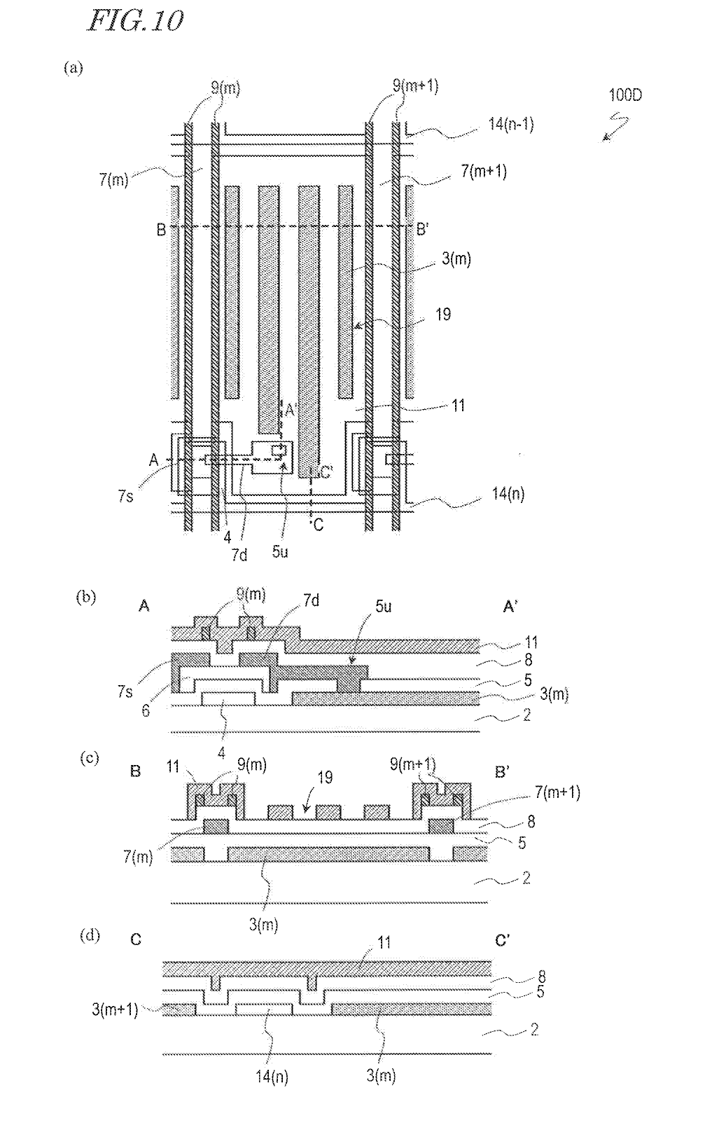

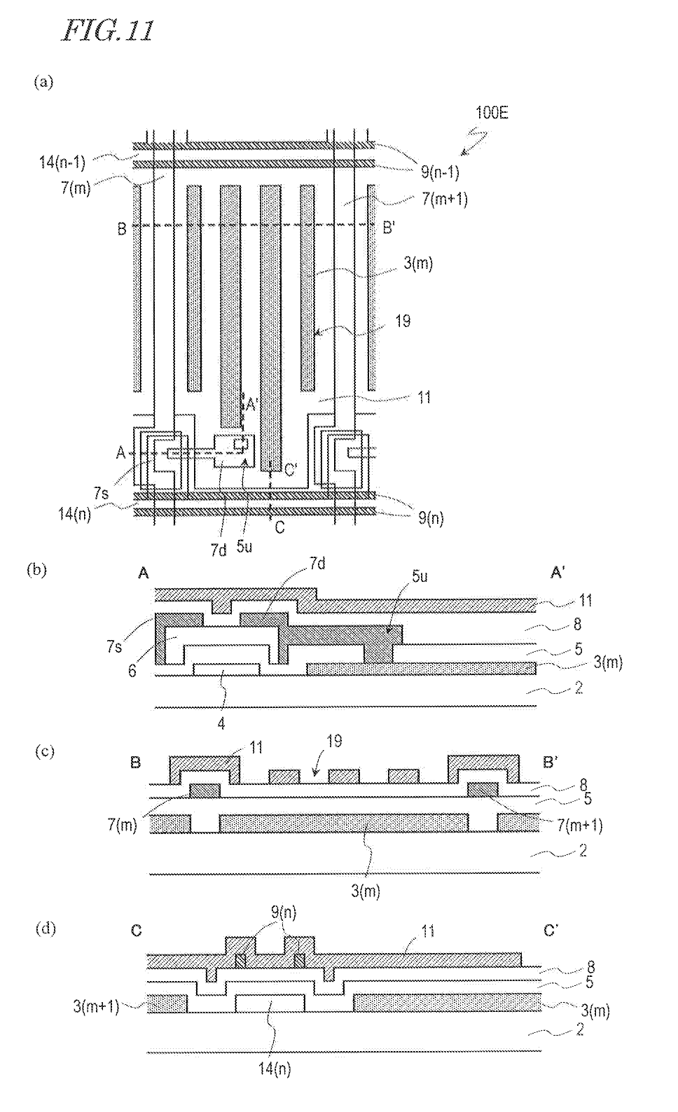

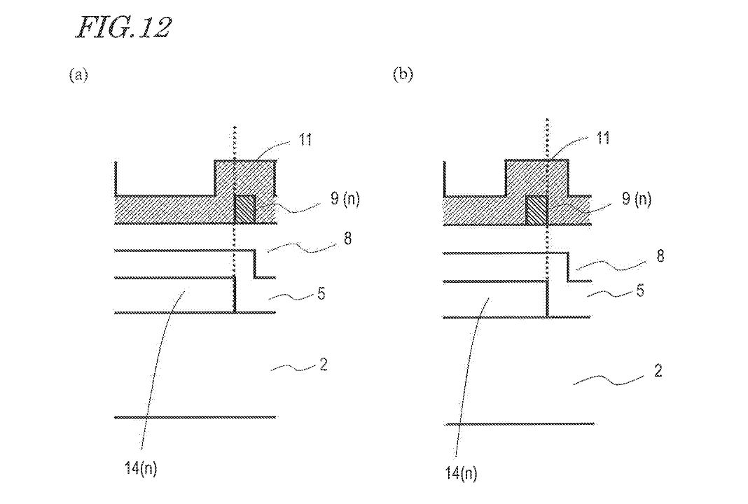

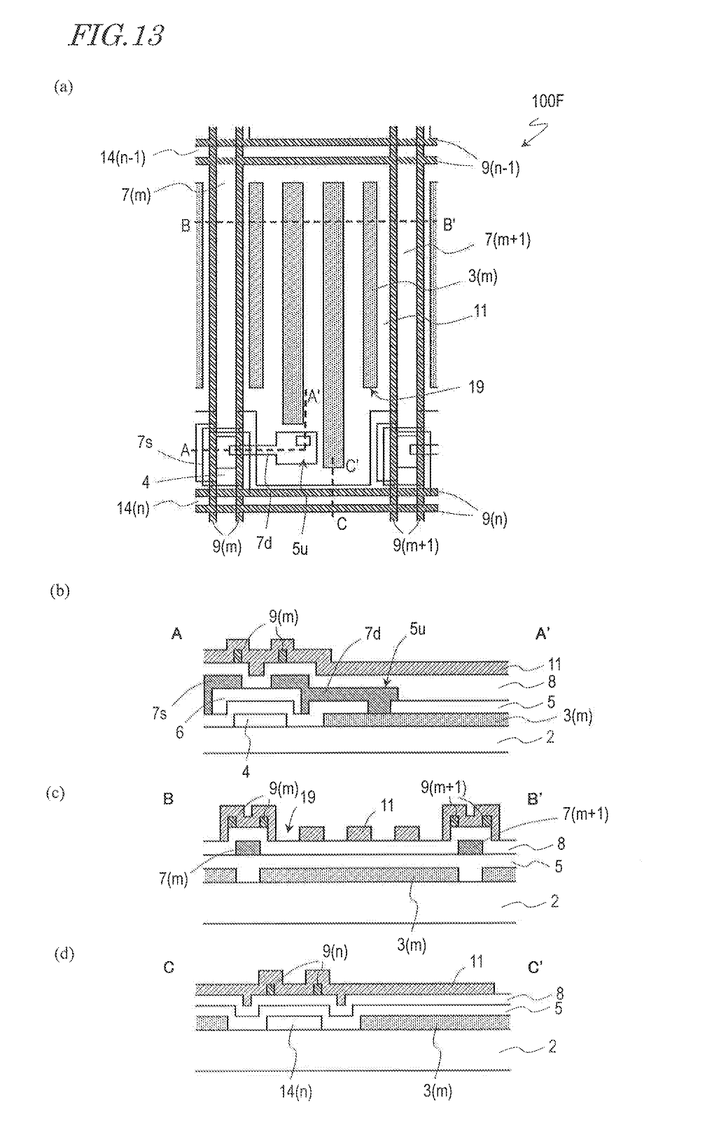

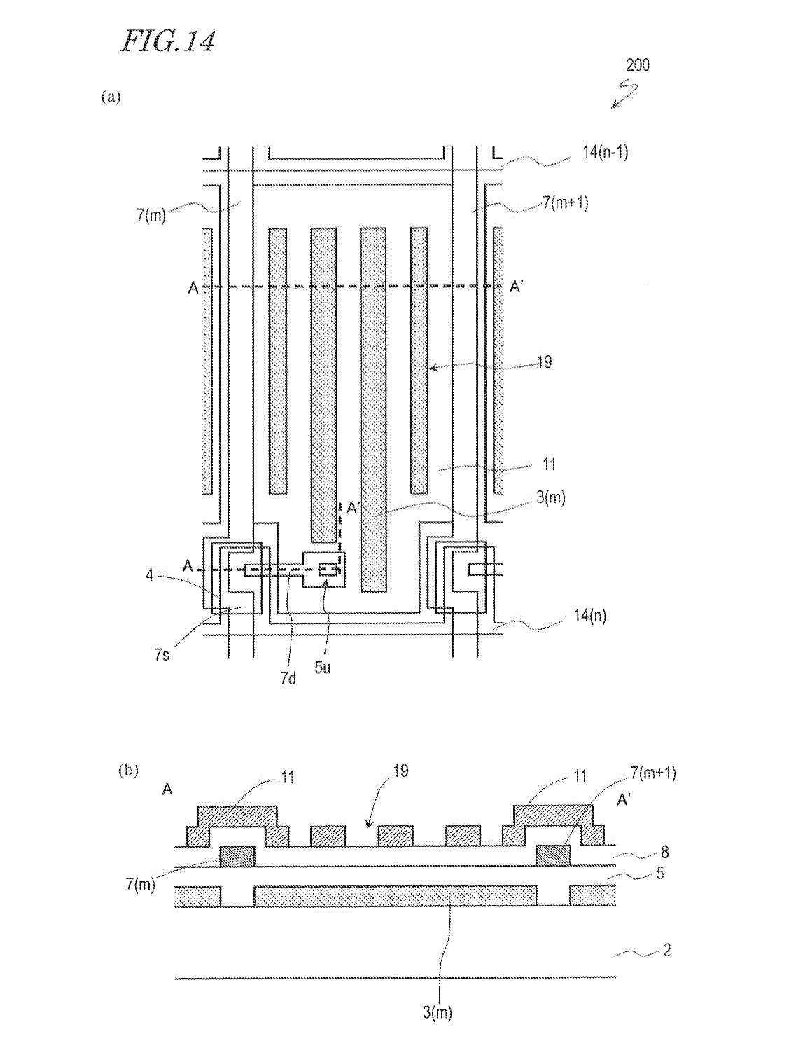

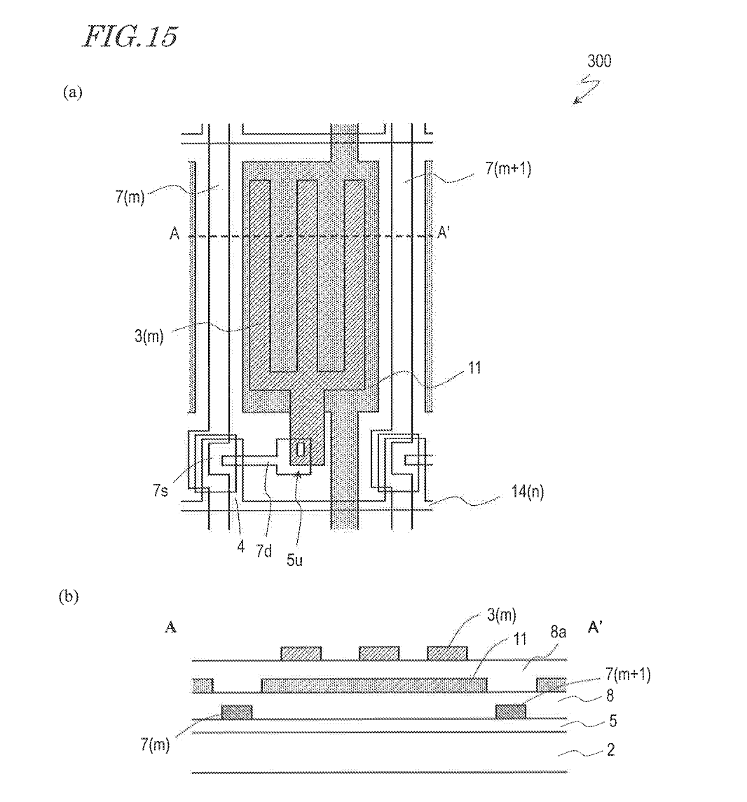

### BRIEF DESCRIPTION OF DRAWINGS

[FIG. 1] (a) is a schematic plan view illustrating a TFT substrate 100A according to an embodiment of the present invention. (b) is a schematic cross-sectional view of the TFT substrate 100A as viewed on the plane A-A′ shown in (a). (c) is a schematic cross-sectional view of the TFT substrate 100A as viewed on the plane B-B′ shown in (a). And (d) is a schematic cross-sectional view of the TFT substrate 100A as viewed on the plane C-C′ shown in (a).

[FIG. 2] (a) and (b) are schematic cross-sectional views illustrating relative arrangements of an auxiliary line 9(m) and a source line 7(m).

[FIG. 3] A block diagram illustrating how the TFT substrate 100A may be fabricated.

[FIG. 4] (a) through (g) are schematic cross-sectional views illustrating how to fabricate the TFT substrate 100A.

[FIG. 5] (a) through (f) are schematic cross-sectional views illustrating a modified method for fabricating the TFT substrate 100A.

[FIG. 6] (a) is a schematic plan view illustrating a TFT substrate 100B according to another embodiment of the present invention. (b) is a schematic cross-sectional view of the TFT substrate 100B as viewed on the plane A-A′ shown in (a). (c) is a schematic cross-sectional view of the TFT substrate 100B as viewed on the plane B-B′ shown in (a). And (d) is a schematic cross-sectional view of the TFT substrate 100B as viewed on the plane C-C′ shown in (a).

[FIG. 7] (a) is a schematic plan view illustrating a TFT substrate 100C according to another embodiment of the present invention. (b) is a schematic cross-sectional view of the TFT substrate 100C as viewed on the plane A-A′ shown in (a). (c) is a schematic cross-sectional view of the TFT substrate 100C as viewed on the plane B-B′ shown in (a). And (d) is a schematic cross-sectional view of the TFT substrate 100C as viewed on the plane C-C′ shown in (a).

[FIG. 8] A block diagram illustrating how the TFT substrate 100C may be fabricated.

[FIG. 9] (a) through (h) are schematic cross-sectional views illustrating how to fabricate the TFT substrate 100C.

[FIG. 10] (a) is a schematic plan view illustrating a TFT substrate 100D according to still another embodiment of the present invention. (b) is a schematic cross-sectional view of the TFT substrate 100D as viewed on the plane A-A′ shown in (a). (c) is a schematic cross-sectional view of the TFT substrate 100D as viewed on the plane B-B′ shown in (a). And (d) is a schematic cross-sectional view of the TFT substrate 100D as viewed on the plane C-C′ shown in (a).

[FIG. 11] (a) is a schematic plan view illustrating a TFT substrate 100E according to yet another embodiment of the present invention. (b) is a schematic cross-sectional view of the TFT substrate 100E as viewed on the plane A-A′ shown in (a). (c) is a schematic cross-sectional view of the TFT substrate 100E as viewed on the plane B-B′ shown in (a). And (d) is a schematic cross-sectional view of the TFT substrate 100E as viewed on the plane C-C′ shown in (a).

[FIG. 12] (a) and (b) are schematic cross-sectional views illustrating relative arrangements of an auxiliary line 9(n) and a gate line 14(n).

[FIG. 13] (a) is a schematic plan view illustrating a TFT substrate 100F according to yet another embodiment of the present invention. (b) is a schematic cross-sectional view of the TFT substrate 100F as viewed on the plane A-A′ shown in (a). (c) is a schematic cross-sectional view of the TFT substrate 100F as viewed on the plane B-B′ shown in (a). And (d) is a schematic cross-sectional view of the TFT substrate 100F as viewed on the plane C-C′ shown in (a).

[FIG. 14] (a) is a schematic cross-sectional view illustrating a TFT substrate 200 as a comparative example, and (b) is a schematic cross-sectional view of the TFT substrate 200 as viewed on the plane A-A′ shown in (a).

[FIG. 15] (a) is a schematic cross-sectional view illustrating a TFT substrate 300 as another comparative example, and (b) is a schematic cross-sectional view of the TFT substrate 300 as viewed on the plane A-A′ shown in (a).

### DESCRIPTION OF EMBODIMENTS

A semiconductor device according to an embodiment of the present invention will now be described with reference to the accompanying drawings. A semiconductor device according to this embodiment may be implemented broadly as an active-matrix substrate or any of various kinds of display devices and electronic devices. A semiconductor device according to an embodiment of the present invention will be described as being applied to a semiconductor device (TFT substrate) for use in a liquid crystal display device.

FIG. 1(a) is a schematic plan view illustrating a TFT substrate 100A according to an embodiment of the present invention. FIG. 1(b) is a schematic cross-sectional view of the TFT substrate 100A as viewed on the plane A-A′ shown in FIG. 1(a). FIG. 1(c) is a schematic cross-sectional view of the TFT substrate 100A as viewed on the plane B-B′ shown in FIG. 1(a). And FIG. 1(d) is a schematic cross-sectional view of the TFT substrate 100A as viewed on the plane C-C′ shown in FIG. 1(a).

As shown in FIGS. 1(a) and 1(b), this TFT substrate 100A includes a substrate 2, a plurality of lines 7(m), 7(m+1), 14(n) and 14(n−1), a TFT 10, a pixel electrode 3(m), a protective layer 8 covering the TFT 10, auxiliary lines 9(m) and 9(m+1) arranged on the protective layer 8, and a common electrode 11 which overlaps with at least a portion of the pixel electrode 3(m) with the protective layer 8 interposed between them and which is electrically connected to the auxiliary lines 9(m) and 9(m+1). These members are assembled together on the substrate 2. The auxiliary lines 9(m) and 9(m+1) are arranged over an arbitrary one 7(m), 7(m+1) of the plurality of lines 7(m), 7(m+1), 14(n) and 14(n−1). The auxiliary lines 9(m) and 9(m+1) have a lower electrical resistance than the common electrode 11. When viewed along a normal to the substrate 2, the auxiliary lines 9(m) and 9(m+1) run along the arbitrary one of the lines 7(m) and 7(m+1). When viewed along a normal to the substrate 2, the common electrode 11 has opening areas 11u(m) and 11u(m+1) which overlap at least partially with the arbitrary one of the lines 7(m) and 7(m+1).

The auxiliary lines 9(m) and 9(m+1) suitably have light shielding property.

In this TFT substrate 100A, opening areas 11u(m) and 11u(m+1) are cut through the common electrode 11. As a result, the parasitic capacitance to be produced between the source lines 7(m), 7(m+1) and the common electrode 11, for example, can be reduced. It should be noted that these opening areas 11(m) and 11(m+1) are suitably provided for the source lines 7(m) and 7(m+1) but do not have to be provided for every source line 7(m), 7(m+1).

In addition, over the source lines 7(m) and 7(m+1), auxiliary lines 9(m) and 9(m+1) having a lower electrical resistance than the common electrode 11 are arranged to be electrically connected to the common electrode 11. As a result, the delay of a signal to be transmitted to the common electrode 11 can be reduced, and therefore, the power dissipation cut be cut down, the display quality can be improved, and the size and/or definition of a display device can be increased.

Furthermore, as will be described in detail later, if the auxiliary lines 9(m) and 9(m+1) have light shielding property and are arranged in the vicinity of the end portions of the source lines 7(m) and 7(m+1), for example, then the leaking light to be produced by disturbance in the orientation of a liquid crystal material near the end portions of the source lines 7(m) and 7(m+1) can be shut out by the auxiliary lines 9(m) and 9(m+1). As a result, a liquid crystal display device including this TFT substrate 100A achieves high display quality. It should be noted that these auxiliary lines 9(m) and 9(m+1) are suitably provided for the source lines 7(m) and 7(m+1) but do not have to be provided for every source line 7(m), 7(m+1). Also, in this TFT substrate 100A, two auxiliary lines 9(m), 9(m+1) are arranged near both ends of their associated source line 7(m), 7(m+1). However, only one of the two auxiliary lines may be provided on either side.

Next, advantages of the TFT substrate 100A will be described with reference to FIG. 14 which illustrates a TFT substrate 200 as a comparative example. FIG. 14(a) is a schematic plan view illustrating a TFT substrate 200 as a comparative example and FIG. 14(b) is a schematic cross-sectional view of the TFT substrate 200 as viewed on the plane A-A′ shown in FIG. 14(a). In FIG. 14, any component also included in the TFT substrate 100A and having substantially the same function as its counterpart is identified by the same reference numeral as its counterpart's and description thereof will be omitted herein to avoid redundancies.

As shown in FIGS. 14(a) and 14(b), the TFT substrate 200 of this comparative example has neither the opening areas 11u(m) and 11u(m+1) nor the auxiliary lines 9(m) and 9(m+1) unlike the TFT substrate 100A.

In this TFT substrate 200, the common electrode 11 overlaps with the source lines 7(m) and 7(m+1) with the protective layer 8 interposed between them in so large an area that the parasitic capacitance increases. As a result, a signal to be transmitted to the common electrode 11 could be delayed.

On the other hand, in the TFT substrate 100A, the opening areas 11u(m) and 11u(m+1) are provided for portions of the common electrode 11 that overlap with the source lines 7(m) and 7(m+1), and therefore, the parasitic capacitance to be produced by the common electrode 11 and the source lines 7(m) and 7(m+1) can be reduced. In this manner, a signal to be transmitted to the common electrode 11 can be prevented from getting delayed.

Furthermore, as shown in FIGS. 1(a) to 1(c), in the TFT substrate 100A, the electrical resistance of the common electrode 11 could increase by providing the opening areas 11u(m) and 11u(m+1) described above. However, such an increase in the electrical resistance of the common electrode 11 can be checked by providing the auxiliary lines 9(m) and 9(m+1) with lower electrical resistance than the common electrode 11. On top of that, by arranging the auxiliary lines 9(m) and 9(m+1) with light shielding property along the end portions of the source lines 7(m) and 7(m+1), respectively, leakage of light can be prevented from being caused by a disturbance in the orientation of the liquid crystal material in the vicinity of the source lines 7(m) and 7(m+1).

Furthermore, in this TFT substrate 100A, the pixel electrode 3(m) overlaps at least partially with the common electrode 11 with the protective layer 8 interposed between them and may form a storage capacitor between them. If the pixel electrode 3(m) and common electrode 11 are made of a transparent electrode material (such as ITO (indium tin oxide)), a decrease in the aperture ratio of a pixel can be minimized. In the following description, such a storage capacitor made of a transparent material will be sometimes hereinafter referred to as a “transparent storage capacitor”.

As shown in FIGS. 1(a) and 1(b), a single TFT 10 is provided for each pixel. Each TFT 10 includes a gate electrode 4, a gate insulating layer 5, a semiconductor layer 6 formed on the gate insulating layer 5, and source and drain electrodes 7s and 7d which are electrically connected to the semiconductor layer 6.

A protective layer 8 is formed over the source and drain electrodes 7s and 7d. On the protective layer 8, auxiliary lines 9(m) and 9(m+1) and a common electrode 11 have been formed.

The pixel electrode 3(m) is formed on the substrate 2. Over the pixel electrode 3(m), the gate insulating layer is formed. Inside a hole 5u cut through the gate insulating layer 5, the pixel electrode 3(m) and the drain electrode 7d are connected together.

As shown in FIGS. 1(a) and 1(c), the TFT substrate 100A includes source lines 7(m) and 7(m+1) which are electrically connected to the source electrode 7s of their associated pixel. The source lines 7(m) and 7(m+1) have been formed on the gate insulating layer 5.

Furthermore, as shown in FIGS. 1(a) and 1(d), in this TFT substrate 100A, a gate line 14(n) is formed between the pixel electrodes 3(m) and 3(m+1) of adjacent pixels. All of the pixel electrodes 3(m) and 3(m+1) and gate line 14(n) are formed between the substrate 2 and the gate insulating layer 5. Also, the common electrode 11 is not divided multiple sections for respective pixels.

The semiconductor layer 6 is suitably an oxide semiconductor layer. As described above, a TFT with an oxide semiconductor layer has mobility which is high enough to have a smaller size and check a decrease in the aperture ratio of a pixel.

Next, the relative arrangement of the auxiliary line 9(m) and source line 7(m) will be described with reference to FIG. 2. FIGS. 2(a) and 2(b) are schematic cross-sectional views illustrating relative arrangements of the auxiliary line 9(m) and the source line 7(m).

As shown in FIG. 2(a), the auxiliary line 9(m) may be arranged so that only an end portion of the auxiliary line 9(m) overlaps with an end portion of the source line 7(m) when viewed along a normal to the substrate 2.

Alternatively, as shown in FIG. 2(b), the auxiliary line 9(m) may also be arranged so that the auxiliary line 9(m) is laid in its entirety over the source line 7(m) and the end portions of the auxiliary line 9(m) are aligned with the end portions of the source line 7(m) when viewed along a normal to the substrate 2.

The auxiliary line 9(m) suitably has a width of 2 μm to 50 μm, for example. The reason is that if the width of the auxiliary line 9(m) were less than 2 μm, the ability to minimize leakage of light due to a disturbance in the orientation of the liquid crystal material could decline. However, if the width were more than 50 μm, then the aperture ratio of a pixel would decrease significantly.

In the example illustrated in FIGS. 1(a) to 1(c), the auxiliary lines 9(m) and 9(m+1) and opening areas 11u(m) and 11u(m+1) are arranged along the source lines 7(m) and 7(m+1), respectively. Alternatively, the auxiliary lines and opening areas may also be arranged along the gate lines 14(n) and 14(n−1). Still alternatively, not only the auxiliary lines 9(m) and 9(m+1) and opening areas 11u(m) and 11u(m+1) may be formed as shown in FIGS. 1(a) to 1(c) but also additional auxiliary lines and opening areas may be provided along the gate lines 14(n) and 14(n−1).

Next, respective components of the TFT substrate 100A will be described in detail one by one.

The substrate 2 is typically a transparent substrate and may be a glass substrate, for example, but may also be a plastic substrate. Examples of the plastic substrates include a substrate made of either a thermosetting resin or a thermoplastic resin and a composite substrate made of these resins and an inorganic fiber (such as glass fiber or a non-woven fabric of glass fiber). A resin material with thermal resistance may be polyethylene terephthalate (PET), polyethylene naphthalate (PEN), polyether sulfone (PES), an acrylic resin, or a polyimide resin, for example. Also, when used in a reflective liquid crystal display device, the substrate 2 may also be a silicon substrate.

Each of the pixel electrodes 3(m), 3(m+1) and common electrode 11 may be formed out of a transparent conductive film (of ITO or IZO™ (indium tin oxide)), for example. The pixel electrodes 3(m), 3(m+1) and common electrode 11 suitably have a thickness of 20 nm to 200 nm, for example. The pixel electrodes 3(m), 3(m+1) and common electrode 11 each have a thickness of about 100 nm, for example.

The gate electrode 4 is electrically connected to its associated gate line 14(n) or 14(n−1). The gate electrode 4 and gate lines 14(n) and 14(n−1) may have a multilayer structure, of which the upper layer is a W (tungsten) layer and the lower layer is a TaN (tantalum nitride) layer, for example. Alternatively, the gate electrode 4 and gate lines 14(n) and 14(n−1) may also have a multilayer structure consisting of Mo (molybdenum), Al (aluminum) and Mo layers or may even have a single-layer structure, a double layer structure, or a multilayer structure consisting of four or more layers. Still alternatively, the gate electrode 4 and gate lines 14 may be made of an element selected from the group consisting of Cu (copper), Al, Cr (chromium), Ta (tantalum), Ti (titanium), Mo and W or an alloy or metal nitride which is comprised mostly of any of these elements. The thickness of the gate electrode 4 and gate lines 14(n) and 14(n−1) suitably falls within the range of about 50 nm to about 600 nm, for example. The gate electrode 4 and gate lines 14(n) and 14(n−1) may each have a thickness of approximately 420 nm, for example.

The gate insulating layer 5 may be a single layer or a multilayer structure of SiO₂ (silicon dioxide), SiNₓ (silicon nitride), SiOₓN_{y} (silicon oxynitride, where x>y), SiNₓO_{y} (silicon nitride oxide, where x>y), Al₂O₃ (aluminum oxide), or tantalum oxide (Ta₂O₅). The thickness of the gate insulating layer 5 suitably falls within the range of about 50 nm to about 600 nm. To form a dense gate insulating layer 5 which causes little gate leakage current at low temperatures, the gate insulating layer 5 is suitably formed using a rare gas of Ar (argon), for example.

The semiconductor layer 6 is suitably an oxide semiconductor layer, for example. If the semiconductor layer 6 is an oxide semiconductor layer, the semiconductor layer 6 can be formed at a lower temperature than a silicon-based semiconductor layer. That is why the semiconductor layer 6 can also be formed on a plastic substrate, for example, and this device is applicable to a flexible display, too. The oxide semiconductor layer may be formed out of an In—Ga—Zn—O based semiconductor film including In (indium), Ga (gallium) and Zn (zinc) at a ratio of 1:1:1, for example. The ratio of In, Ga and Zn may be selected appropriately. If an amorphous In—Ga—Zn—O based semiconductor film is used as the In—Ga—Zn—O based semiconductor film, the In—Ga—Zn—O based semiconductor film can be formed at a low temperature and high mobility can be achieved. However, the amorphous In—Ga—Zn—O based semiconductor film may be replaced with an In—Ga—Zn—O based semiconductor film which exhibits crystallinity with respect to a predetermined crystal axis (C-axis). A TFT including such an In—Ga—Zn—O based semiconductor exhibiting crystallinity is disclosed, for example, in Japanese Laid-Open Patent Publication No. 2012-134475, the entire disclosure of which is hereby incorporated by reference. The semiconductor layer 6 does not have to be formed out of an In—Ga—Zn—O based semiconductor film, but may also be formed out of any other suitable oxide semiconductor film such as a Zn—O based semiconductor (ZnO) film, an In—Zn—O based semiconductor (IZO) film, a Zn—Ti—O based semiconductor (ZTO) film, a Cd—Ge—O based semiconductor film, a Cd—Pb—O based semiconductor film, a CdO (cadmium oxide) film, or an Mg—Zn—O based semiconductor film. Furthermore, the oxide semiconductor layer may also be made of ZnO in an amorphous state, a polycrystalline state, or a microcrystalline state (which is a mixture of amorphous and polycrystalline states) to which one or multiple dopant elements selected from the group consisting of Group I, Group XIII, Group XIV, Group XV and Group XVII elements have been added, or may even be ZnO to which no dopant elements have been added at all. The thickness of the semiconductor layer 6 suitably falls within the range of about 30 nm to about 100 nm, for example. The semiconductor layer 6 may have a thickness of approximately 50 nm, for example. Alternatively, the semiconductor layer 6 may also be a silicon based semiconductor layer such an amorphous silicon (a-Si) layer, a polysilicon (p-Si) layer, or a microcrystalline silicon (μ-Si) layer.

The source electrode 7s, drain electrode 7d, and source lines 7(m) and 7(m+1) may each have a multilayer structure consisting of a lower layer and an upper layer formed on the lower layer. The lower and upper layers are made of mutually different metals. For example, the lower layer may be made of MoN (molybdenum nitride) and the upper layer may be made of Mo. Particularly when the pixel electrode 3(m) is formed out of a transparent conductive film (such as an ITO film), the lower layer in contact with the pixel electrode 3(m) is suitably made of a refractory metal nitride. In that case, the pixel electrode 3(m) formed out of a transparent conductive film and the drain electrode 7d can contact with each other more closely, and the contact resistance between the pixel electrode 3(m) and the drain electrode 7d can be reduced as well. On top of that, the pixel electrode 3(m) that is formed can be prevented from having its surface state affected by the manufacturing process that the pixel electrode 3(m) has to go through after that. Alternatively, the source and drain electrodes 7s, 7d may also have a multilayer structure consisting of Mo, Al and Mo layers or may even have a single-layer structure, a double layer structure, or a multilayer structure consisting of four or more layers. Still alternatively, the source electrode 7s, drain electrode 7d, and source lines 7(m) and 7(m+1) may be made of an element selected from the group consisting of Al, Cr, Ta, Ti, Mo and W or an alloy or metal nitride which is comprised mostly of any of these elements. The thickness of the source electrode 7s, drain electrode 7d, and source lines 7(m) and 7(m+1) suitably falls within the range of about 50 nm to about 600 nm, for example. The source electrode 7s, drain electrode 7d, and source lines 7(m) and 7(m+1) may each have a thickness of approximately 350 nm, for example.

The protective layer 8 may be made of SiNₓ, for example, and is formed over the source electrode 7s, drain electrode 7d, and source lines 7(m) and 7(m+1). The protective layer 8 may be arranged between the common electrode 11 and the pixel electrode 3(m), for example. If a storage capacitor is formed of the transparent common electrode 11 and pixel electrode 3(m) and the transparent protective layer 8, a display panel with a high aperture ratio can be fabricated when this TFT substrate 100A is used in a display panel. The thickness of the protective layer 8 suitably falls within the range of about 50 nm to about 300 nm, for example. The protective layer 8 may have a thickness of approximately 200 nm, for example. Alternatively, the protective layer 8 may also be made of SiOₓN_{y} (silicon oxynitride, where x>y), SiNₓO_{y} (silicon nitride oxide, where x>y), Al₂O₃ (aluminum oxide), or tantalum oxide (Ta₂O₅).

This TFT substrate 100A may be used in a fringe field switching (FFS) mode liquid crystal display device, for example. In that case, a display signal voltage is applied to the lower pixel electrode and either a common voltage or a counter voltage is applied to the upper common electrode 11. At least one slit 19 is cut through the common electrode 11 (see FIGS. 1(a) and 1(c)).

Next, it will be described how to fabricate the TFT substrate 100A according to an embodiment of the present invention.

A method for fabricating the TFT substrate 100A includes the steps of (a) providing a substrate 2 and (b) forming a plurality of lines 7(m), 7 (m+1), 14 and a TFT 10 on the substrate 2. The method for fabricating the TFT substrate 100A further includes the steps of (c) forming a protective layer 8 that covers the TFT 100, and (d) forming a conductive film 11′ on the protective layer 8 and forming another conductive film 9′, having a lower electrical resistance than the former conductive film 11′, on the conductive film 11′. The method for fabricating the TFT substrate 100A further includes the steps of (e) patterning the conductive films 11′ and 9′ through a single photomask by half-tone exposure process, thereby forming, out of the conductive film 11′, a common electrode 11 which has opening areas 11u(m), 11u(m+1) that overlap at least partially with an arbitrary one 7(m), 7(m+1) of the plurality of lines 7(m), 7(m+1), 14 and also forming auxiliary lines 9(m), 9(m+1) which run along the arbitrary one 7(m), 7(m+1) of the lines 7(m), 7(m+1), 14 out of the conductive film 9′.

According to such a method for fabricating the TFT substrate 100A, the TFT substrate 100A can be fabricated without increasing the manufacturing cost.

The step (b) may include the step (b1) of forming a pixel electrode 3 on the substrate 2, and the step (e) may include the step (e1) of forming the common electrode 11 so that the common electrode 11 overlaps with the pixel electrode 3 with the protective layer 8 interposed between them.

The method for fabricating the TFT substrate 100A may further include the steps of (f) forming an insulating layer 8a over the auxiliary lines 9(m) and 9(m+1), and (g) forming a pixel electrode 3 which overlaps with the common electrode 11 with the insulating layer 8a interposed between them.

Next, an exemplary method for fabricating the TFT substrate 100A will be described with reference to FIGS. 3 and 4. FIG. 3 is a block diagram illustrating how to fabricate the TFT substrate 100A. FIGS. 4(a) through 4(g) are schematic cross-sectional views illustrating how to fabricate the TFT substrate 100A.

As shown in FIG. 3, the manufacturing process of the TFT substrate 100A includes a pixel electrode forming process step PX, a gate electrode forming process step GT, a gate insulating layer/semiconductor layer forming process step GI/PS, a source/drain electrode forming process step SD, a protective layer forming process step PAS, an auxiliary line forming process step A and a common electrode forming process step CT. And the manufacturing process advances in this order.

Specific manufacturing process steps will now be described with reference to FIGS. 4(a) through 4(g).

As shown in FIG. 4(a), in the pixel electrode forming process step PX, a conductive film (not shown), which may be a transparent conductive film such as an ITO film, is formed on the substrate 2 by sputtering process, for example, and then patterned by photolithographic and wet etching processes, for example, thereby forming a pixel electrode 3. After the pixel electrode 3 has been obtained by patterning, the resist (not shown) that has been used in the patterning process is stripped.

Subsequently, as shown in FIG. 4(b), in the gate electrode forming process step GT, a conductive film is deposited over the substrate 2 by sputtering process, for example, and then patterned by photolithographic process and wet or dry etching process, for example, thereby forming a gate electrode 4. Although not shown in FIG. 4(b), a gate line is also formed in this process step. The gate electrode 4 is formed so as not to be electrically connected to the pixel electrode 3. After the gate electrode 4 has been formed by patterning, the resist (not shown) that has been used for the patterning process is stripped.

Thereafter, as shown in FIG. 4(c), in the gate insulating layer/semiconductor layer forming process step GI/PS, an insulating film (not shown) is deposited over the gate electrode 4 and pixel electrode 3 by CVD (chemical vapor deposition) process, for example. Next, the insulating film is patterned by photolithographic and dry etching processes, for example, thereby forming a gate insulating layer 5, through which a hole 5u that exposes the pixel electrode 3 partially is cut. After the gate insulating layer 5 has been formed by patterning, the resist (not shown) that has been used for the patterning process is stripped.

Next, a semiconductor film (not shown), which may be an In—Ga—Zn—O based semiconductor film, for example, is formed over the gate insulating layer 5 by sputtering process, for example, and then patterned by photolithographic and dry etching processes, for example, thereby forming a semiconductor layer 6. The semiconductor layer 6 is formed so as to overlap with the gate electrode 4 with the gate insulating layer 5 interposed between them. After the semiconductor layer 6 has been formed by patterning, the resist (not shown) that has been used for the patterning process is stripped.

Then, as shown in FIG. 4(d), in the source/drain electrode forming process step SD, a conductive film (not shown) is deposited over the semiconductor layer 6 by sputtering process, for example. Thereafter, this conductive film is patterned by photolithographic and wet etching processes, thereby forming source and drain electrodes 7s and 7d. Although not shown in FIG. 4(d), a source line is also formed in this process step. After the source and drain electrodes 7s, 7d have been formed by patterning, the resist (not shown) that has been used for the patterning process is stripped.

The source and drain electrodes 7s, 7d are electrically connected to the semiconductor layer 6. The drain electrode 7d is also connected to the pixel electrode 3 inside the hole 5u.

Next, as shown in FIG. 4(e), in the protective layer forming process step PAS, an insulating film (not shown) is deposited over the source and drain electrodes 7s, 7d by CVD process, for example, and then patterned by photolithographic and dry etching processes, for example, thereby forming a protective layer 8. After the protective layer 8 has been formed by patterning, the resist (not shown) that has been used for the patterning process is stripped.

Subsequently, as shown in FIG. 4(f), in the auxiliary line forming process step A, a conductive film (not shown) is deposited over the protective layer 8 by sputtering process, for example, and then patterned by photolithographic and wet etching processes, for example, thereby forming an auxiliary line 9. After the auxiliary line 9 has been formed by patterning, the resist (not shown) that has been used for the patterning process is stripped. As described above, the auxiliary line 9 is formed to run along the source lines 7(m) and 7(m+1) (see FIG. 1(a)).

Then, as shown in FIG. 4(g), in the common electrode forming process step CT, a conductive film (not shown), which may be a transparent conductive film, is deposited over the protective layer 8 by sputtering process, for example. Thereafter, the conductive film is patterned by photolithographic and wet etching processes, thereby forming a common electrode 11. After the common electrode 11 has been formed by patterning, the resist (not shown) that has been used for the patterning process is stripped.

The common electrode 11 is formed to have an opening area 11u. As described above, the opening area 11u is formed to overlap at least partially with the source lines 7(m) and 7(m+1) when viewed along a normal to the substrate 2 (see FIG. 1(a)).

Also, the common electrode 11 is formed so as to overlap with a part of the pixel electrode 3 with the gate insulating layer 5 and protective layer 8 interposed between them. Furthermore, the common electrode 11 is formed to be in contact with, and electrically connected to, the auxiliary line 9.

Next, a modified method for fabricating the TFT substrate 100A will be described with reference to FIG. 5. FIGS. 5(a) through 5(f) are schematic cross-sectional views illustrating a modified method for fabricating the TFT substrate 100A.

This modified example of a method for fabricating the TFT substrate 100A to be described below with reference to FIGS. 5(a) through 5(f) is different from the method for fabricating the TFT substrate 100A that has already been described with reference to FIGS. 4(a) through 4(g) only in the auxiliary line forming process step A and common electrode forming process step CT among the respective process steps in the block diagram shown in FIG. 3. Thus, the following description of the modified method for fabricating the TFT substrate 100A will be focused on the auxiliary line forming process step A and common electrode forming process step CT.

As described above, a pixel electrode 3, a gate electrode 4, a gate insulating layer 5, a semiconductor layer 6, a source electrode 7s, a drain electrode 7d and a protective layer 8 are formed on the substrate 2 by the method that has already been described with reference to FIGS. 4(a) through 4(e).

Next, in the auxiliary line forming process step A, a conductive film (such as a transparent conductive film) 11′ is deposited over the protective layer 8 by sputtering process as shown in FIG. 5(a). After that, another conductive film 9′ is deposited over the conductive film 11′ by sputtering process.

Subsequently, as shown in FIG. 5(b), resist films R1 and R2 with mutually different thicknesses are formed on the conductive film 9′ by half-tone exposure process using a single photomask (such as a half-tone mask). It should be noted that there is a region in which the conductive film 9′ is not covered with the resist films R1 and R2.

Thereafter, as shown in FIG. 5(c), the conductive films 9′ and 11′ are patterned simultaneously by performing a wet etching process using the resist films R1 and R2 as a mask. As a result, a conductive layer 9a is formed out of the conductive film 9′ and a common electrode 11 is formed out of the conductive film 11′.

Next, as shown in FIG. 5(d), the resist films R1 and R2 are dry-etched and turned into a resist film R1′. Subsequently, a dry etching process is further carried out using the resist film R1′ as a mask, thereby patterning the conductive layer 9a and forming auxiliary lines 9.

And then the resist film R1′ is stripped by a known method as shown in FIG. 5(e).

As can be seen, according to this modified method for fabricating the TFT substrate 100A, auxiliary lines 9 and a common electrode 11 can be formed with a single photomask, and therefore, the manufacturing cost can be cut down.

Next, a TFT substrate 100B according to another embodiment of the present invention will be described with reference to FIG. 6. FIG. 6(a) is a schematic plan view illustrating a TFT substrate 100B according to another embodiment of the present invention. FIG. 6(b) is a schematic cross-sectional view of the TFT substrate 100B as viewed on the plane A-A′ shown in FIG. 6(a). FIG. 6(c) is a schematic cross-sectional view of the TFT substrate 100B as viewed on the plane B-B′ shown in FIG. 6(a). And FIG. 6(d) is a schematic cross-sectional view of the TFT substrate 100B as viewed on the plane C-C′ shown in FIG. 6(a). Any component also included in the TFT substrate 100A and having substantially the same function as its counterpart is identified by the same reference numeral as its counterpart's and description thereof will be omitted herein to avoid redundancies.

As shown in FIGS. 6(a) and 6(d), in this TFT substrate 100B, auxiliary lines 9(n) and 9(n−1) are arranged along the gate lines 14(n) and 14(n−1), respectively, which is a major difference from the TFT substrate 100A.

As can be seen from FIGS. 6(a), 6(c) and 6(d), opening areas 11u(m) and 11u(m+1) are arranged along the source lines 7(m) and 7(m+1), respectively, and the auxiliary lines 9(n) and 9(n−1) are arranged along the gate lines 14(n) and 14(n−1), respectively.

Depending on the design, if the opening areas 11u(m) and 11u(m+1) and auxiliary lines 9(m) and 9(m+1) are arranged along the same pair of lines as in the TFT substrate 100A, the aperture ratio may decrease in some cases. However, if the opening areas 11u(m) and 11u(m+1) and auxiliary lines 9(n) and 9(n−1) are arranged along two different pairs of lines as in this TFT substrate 100B, then the parasitic capacitance can be reduced and leakage of light due to a disturbance in the orientation of a liquid crystal material can be minimized without causing a decrease in the aperture ratio of a pixel and other problems. As a result, the flexibility of the design process can be increased.

Optionally, instead of arranging the opening areas 11u(m) and 11u(m+1) along the source lines 7(m) and 7(m+1), respectively, and arranging the auxiliary lines 9(n) and 9(n−1) along the gate lines 14(n) and 14(n−1), respectively, the opening areas may be arranged along the gate lines 14(n) and 14(n−1) and the auxiliary lines may be arranged along the source lines 7(m) and 7(m+1).

Next, a TFT substrate 100C according to still another embodiment of the present invention will be described with reference to FIG. 7. FIG. 7(a) is a schematic plan view illustrating a TFT substrate 100C according to another embodiment of the present invention. FIG. 7(b) is a schematic cross-sectional view of the TFT substrate 100C as viewed on the plane A-A′ shown in FIG. 7(a). FIG. 7(c) is a schematic cross-sectional view of the TFT substrate 100C as viewed on the plane B-B′ shown in FIG. 7(a). And FIG. 7(d) is a schematic cross-sectional view of the TFT substrate 100C as viewed on the plane C-C′ shown in FIG. 7(a). Any component also included in the TFT substrate 100A and having substantially the same function as its counterpart is identified by the same reference numeral as its counterpart's and description thereof will be omitted herein to avoid redundancies.

In this TFT substrate 100C, the pixel electrode 3(m) is arranged on an insulating layer 8a which is formed over the common electrode 11, opening areas 3u(m) and 3u(m+1) are provided in the pixel electrode 3(m), not the common electrode 11, and slits are cut through neither the pixel electrode 3(m) nor the common electrode 11, which are major differences from the TFT substrate 100A.

In this TFT substrate 100C, the pixel electrode 3(m) is located closer to the liquid crystal layer (i.e., more distant from the substrate 2) than the common electrode 11 is. That is why this TFT substrate 100C is applicable to not only a liquid crystal display device operating in a lateral electric field mode such as the FFS mode but also a liquid crystal display device operating in a transverse electric field mode such as the VA (vertical alignment) mode. As a result, with this TFT substrate 100C, the display mode can be selected from a wider variety.

The insulating layer 8a is made of a material which can make the protective layer 8. The insulating layer 8a suitably has a thickness of approximately 50 to 300 nm.

Optionally, opening areas 11u(m) and 11u(m+1) may be provided for the common electrode 11 as in the TFT substrate 100A. Also, auxiliary lines 9(n) and 9(n−1) may be formed as in the TFT substrate 100B. The patterns of opening areas and auxiliary lines which may be adopted in the TFT substrates 100A and 100B may also be adopted in this TFT substrate 100C.

Next, advantages of this TFT substrate 100C will be described with reference to FIG. 15 which illustrates a TFT substrate 300 as a comparative example. FIG. 15(a) is a schematic plan view illustrating a TFT substrate 300 as a comparative example and FIG. 15(b) is a schematic cross-sectional view of the TFT substrate 300 as viewed on the plane A-A′ shown in FIG. 15(a). In FIG. 15, any component also included in the TFT substrate 100C and having substantially the same function as its counterpart is identified by the same reference numeral as its counterpart's and description thereof will be omitted herein to avoid redundancies.

As shown in FIGS. 15(a) and 15(b), the TFT substrate 300 of this comparative example has a structure in which the pixel electrode 3(m) does not overlap with the source lines 7(m) and 7(m+1) with an insulating layer (which may be the protective layer 8 or the insulating layer 8a, for example) interposed between them, thus avoiding an increase in parasitic capacitance. The TFT substrate 300 of this comparative example, however, has no auxiliary lines 9(m) and 9(m+1) unlike the TFT substrate 100C, and therefore, leakage of light could be caused due to a disturbance in the orientation of the liquid crystal material around the end portions of the source lines 7(m) and 7(m+1) and the electrical resistance of the common electrode 11 could increase, which are problems.

On the other hand, by providing auxiliary lines 9(m) and 9(m+1) with a lower electrical resistance than the common electrode 11 as shown in FIGS. 7(a) to 7(c), the electrical resistance value of the common electrode 11 can be decreased. In addition, by arranging auxiliary lines 9(m) and 9(m+1) with light shielding property along the end portions of the source lines 7(m) and 7(m+1), respectively, leakage of light that could be caused due to a disturbance in the orientation of the liquid crystal material around the source lines 7(m) and 7(m+1) can be prevented.

Next, an exemplary method for fabricating the TFT substrate 100C will be described with reference to FIGS. 8 and 9. FIG. 8 is a block diagram illustrating how the TFT substrate 100C may be fabricated. FIGS. 9(a) through 9(h) are schematic cross-sectional views illustrating how to fabricate the TFT substrate 100C.

As shown in FIG. 8, the manufacturing process of the TFT substrate 100C includes a gate electrode forming process step GT, a gate insulating layer/semiconductor layer forming process step GI/PS, a source/drain electrode forming process step SD, a protective layer forming process step PAS, a common electrode forming process step CT, an insulating layer forming process step PAS2, and a pixel electrode forming process step PX. And the manufacturing process advances in this order.

Specific manufacturing process steps will now be described with reference to FIGS. 9(a) through 9(h).

First of all, in the gate electrode forming process step GT, a gate electrode 4 and a gate line (not shown) are formed by the method described above as shown in FIG. 9(a).

Next, in the gate insulating layer/semiconductor layer forming process step GI/PS, a gate insulating layer 5 is formed over the gate electrode 4 and a pixel electrode 3 by CVD process or any other suitable process as shown in FIG. 9(b).

Subsequently, a semiconductor layer 6 is formed on the gate insulating layer 5 by the method described above. The semiconductor layer 6 is arranged to overlap with the gate electrode 4 with the gate insulating layer 5 interposed between them.

Thereafter, in the source/drain electrode forming process step SD, a source electrode 7s, a drain electrode 7d and source lines (not shown) are formed by the method described above as shown in FIG. 9(c). The source and drain electrodes 7s and 7d are electrically connected to the semiconductor layer 6.

Next, in the protective layer forming process step PAS, a protective layer 8 is formed over the source and drain electrodes 7s, 7d by the method described above as shown in FIG. 9(d).

Next, in the auxiliary line forming process step A, auxiliary lines 9 are formed on the protective layer 8 by the method described above as shown in FIG. 9(e). The auxiliary lines 9 are arranged along the source lines 7(m) and 7(m+1) (see FIG. 7(a)).

Thereafter, in the common electrode forming process step CT, a common electrode 11 is formed on the protective layer 8 by the method described above as shown in FIG. 9(f).

Then, in the insulating layer forming process step PAS2, an insulating layer 8a is deposited over the common electrode 11 by CVD process, photolithographic process and dry etching process, for example, as shown in FIG. 9(g). In this process step, a hole 5v which exposes a portion of the drain electrode 7d is cut through the insulating layer 8a and the protective layer 8.

Next, in the pixel electrode forming process step PX, a pixel electrode 3 is formed on the insulating layer 8a by the method described above as shown in FIG. 9(h). The pixel electrode 3 is connected to the drain electrode 7d inside the hole 5v.

The pixel electrode 3 is formed so as to overlap with a portion of the common electrode 11 with the insulating layer 8a interposed between them.

It should be noted that in the auxiliary line forming process step A and common electrode forming process step CT shown in FIG. 8, the method that has already been described with reference to FIGS. 5(a) through 5(f) may be adopted. As a result, the number of photomasks to use can be reduced and the manufacturing can be cut down.

Next, a TFT substrate 100D according to still another embodiment of the present invention will be described with reference to FIG. 10. FIG. 10(a) is a schematic plan view illustrating a TFT substrate 100D according to another embodiment of the present invention. FIG. 10(b) is a schematic cross-sectional view of the TFT substrate 100D as viewed on the plane A-A′ shown in FIG. 10(a). FIG. 10(c) is a schematic cross-sectional view of the TFT substrate 100D as viewed on the plane B-B′ shown in FIG. 10(a). And FIG. 10(d) is a schematic cross-sectional view of the TFT substrate 100D as viewed on the plane C-C′ shown in FIG. 10(a). Any component also included in the TFT substrate 100A and having substantially the same function as its counterpart is identified by the same reference numeral as its counterpart's and description thereof will be omitted herein to avoid redundancies.

In this TFT substrate 100D, the common electrode 11 has no opening areas 11u(m) and 11u(m+1), which is a major difference from the TFT substrate 100A.

However, this TFT substrate 100D has auxiliary lines 9(m) and 9(m+1) as shown in FIGS. 10(a) to 10(c). As a result, the delay of a signal to be transmitted to the common electrode 11 can be reduced, and therefore, the power dissipation cut be cut down, the display quality can be improved, and the size and/or definition of a display device can be increased.

Furthermore, if the auxiliary lines 9(m) and 9(m+1) have light shielding property, then the leaking light to be produced by disturbance in the orientation of a liquid crystal material can be shut out, and a decline in display quality can be avoided.

Next, a TFT substrate 100E according to still another embodiment of the present invention will be described with reference to FIG. 11. FIG. 11(a) is a schematic plan view illustrating a TFT substrate 100E according to still another embodiment of the present invention. FIG. 11(b) is a schematic cross-sectional view of the TFT substrate 100E as viewed on the plane A-A′ shown in FIG. 11(a). FIG. 11(c) is a schematic cross-sectional view of the TFT substrate 100E as viewed on the plane B-B′ shown in FIG. 11(a). And FIG. 11(d) is a schematic cross-sectional view of the TFT substrate 100E as viewed on the plane C-C′ shown in FIG. 11(a). Any component also included in the TFT substrate 100A and having substantially the same function as its counterpart is identified by the same reference numeral as its counterpart's and description thereof will be omitted herein to avoid redundancies.

In this TFT substrate 100E, the auxiliary lines 9(n) and 9(n−1) are arranged along the gate lines 14(n) and 14(n−1), respectively, which is a major difference from the TFT substrate 100D.

However, this TFT substrate 100E has auxiliary lines 9(n) and 9(n−1) which are arranged along the gate lines 14(n) and 14(n−1), respectively, as shown in FIGS. 10(a), 10(c) and 10(d). As a result, the delay of a signal to be transmitted to the common electrode 11 can be reduced, and therefore, the power dissipation cut be cut down, the display quality can be improved, and the size and/or definition of a display device can be increased.

Furthermore, if the auxiliary lines 9(n) and 9(n−1) have light shielding property, then the leaking light to be produced by disturbance in the orientation of a liquid crystal material can be shut out, and a decline in display quality can be avoided.

Next, the relative arrangement of the auxiliary line 9(n) and gate line 14(n) will be described with reference to FIG. 12. FIGS. 12(a) and 12(b) are schematic cross-sectional views illustrating relative arrangements of the auxiliary line 9(n) and the gate line 14(n).

As shown in FIG. 12(a), the auxiliary line 9(n) may be arranged so that only an end portion of the auxiliary line 9(n) overlaps with an end portion of the gate line 14(n) when viewed along a normal to the substrate 2.

Alternatively, as shown in FIG. 12(b), the auxiliary line 9(n) may also be arranged so that the auxiliary line 9(n) is laid in its entirety over the gate line 14(n) and the end portions of the auxiliary line 9(n) are aligned with the end portions of the gate line 14(n) when viewed along a normal to the substrate 2.

The auxiliary line 9(n) suitably has a width of 2 μm to 50 μm, for example. The reason is that if the width of the auxiliary line 9(n) were less than 2 μm, the ability to minimize leakage of light due to a disturbance in the orientation of the liquid crystal material could decline. However, if the width were more than 50 μm, then the aperture ratio of a pixel would decrease significantly.

Next, a TFT substrate 100F according to yet another embodiment of the present invention will be described with reference to FIG. 13. FIG. 13(a) is a schematic plan view illustrating a TFT substrate 100F according to yet another embodiment of the present invention. FIG. 13(b) is a schematic cross-sectional view of the TFT substrate 100F as viewed on the plane A-A′ shown in FIG. 13(a). FIG. 13(c) is a schematic cross-sectional view of the TFT substrate 100F as viewed on the plane B-B′ shown in FIG. 13(a). And FIG. 13(d) is a schematic cross-sectional view of the TFT substrate 100F as viewed on the plane C-C′ shown in FIG. 13(a). Any component also included in the TFT substrate 100A and having substantially the same function as its counterpart is identified by the same reference numeral as its counterpart's and description thereof will be omitted herein to avoid redundancies.

This TFT substrate 100F has a configuration in which the auxiliary lines 9(n) and 9(n−1) that the TFT substrate 100E shown in FIG. 11(a) has are added to the TFT substrate 100D. That is to say, this TFT substrate 100F includes not only the auxiliary lines 9(m) and 9(m+1) that are arranged along the source lines 7(m) and 7(m+1), respectively, but also auxiliary lines 9(n) and 9(n−1) which are arranged along the gate lines 14(n) and 14(n−1), respectively.

In the TFT substrates 100A through 100F described above, the common electrode 11 is supposed to be a transparent electrode which is formed out of a transparent conductive film (such as an ITO film). However, this transparent electrode does not have to function as a common electrode but may also function as just an electrode with a transparent storage capacitor as well.

Also, each of the TFT substrates 100A through 100F described above has a double-layer electrode structure including the pixel electrode 3(m) and the common electrode 11. However, when a TFT substrate for use in a VA mode liquid crystal display device is fabricated, for example, the common electrode 11 may be omitted.

As can be seen from the foregoing description, embodiments of the present invention provide a semiconductor device which can minimize a decline in display quality and a method for fabricating such a device.

### INDUSTRIAL APPLICABILITY

Embodiments of the present invention are applicable broadly to various types of devices including a thin-film transistor. Examples of such devices include circuit boards such as an active-matrix substrate, display devices such as a liquid crystal display, an organic electroluminescence (EL) display, and an inorganic electroluminescence display, image capture devices such as an image sensor, and electronic devices such as an image input device and a fingerprint scanner.

### REFERENCE SIGNS LIST

2 substrate
3(m), 3(m+1), 3 pixel electrode
4 gate electrode
5 gate insulating layer
5u hole
6 semiconductor layer
7(m), 7(m+1) source line
7s source electrode
7d drain electrode
8 protective layer
8a insulating layer
9(m), 9(m+1), 9(n), 9(n−1) auxiliary line
10 TFT
11 common electrode
11u(m), 11u(m+1) opening area
14u(n), 14u(n−1) gate line
19 slit
100A TFT substrate

1. A semiconductor device comprising: a substrate; a plurality of lines; a thin-film transistor including a semiconductor layer as its active layer; a pixel electrode; a protective layer covering the thin-film transistor; an auxiliary line arranged on the protective layer; and a common electrode which overlaps with at least a portion of the pixel electrode with the protective layer interposed between them and which is electrically connected to the auxiliary line, the lines, transistor, pixel electrode, protective layer, auxiliary line and common electrode being assembled together on the substrate,
wherein the auxiliary line is arranged over an arbitrary one of the plurality of lines,
the auxiliary line has a lower electrical resistance than the common electrode,
when viewed along a normal to the substrate, the auxiliary line runs along the arbitrary one of the lines, and
when viewed along a normal to the substrate, the common electrode has a first opening area which overlaps at least partially with the arbitrary one of the lines.

2. The semiconductor device of claim 1, wherein the auxiliary line has light shielding property.

3. The semiconductor device of claim 1, further comprising an insulating layer formed over the common electrode, and wherein
the pixel electrode is formed on the insulating layer.

4. The semiconductor device of claim 3, wherein the pixel electrode has a second opening area which overlaps at least partially with the arbitrary one of the lines.

5. The semiconductor device of claim 1, wherein the semiconductor layer is an oxide semiconductor layer.

6. The semiconductor device of claim 5, wherein the oxide semiconductor layer includes In, Ga and Zn.

7. A method for fabricating a semiconductor device, the method comprising the steps of:
(a) providing a substrate;
(b) forming a plurality of lines and a thin-film transistor on the substrate, the thin-film transistor including a semiconductor layer as its active layer;
(c) forming a protective layer that covers the thin-film transistor;
(d) forming a first conductive film on the protective layer and forming a second conductive film on the first conductive film, the second conductive film having a lower electrical resistance than the first conductive film; and
(e) patterning the first and second conductive films through a single photomask by half-tone exposure process, thereby forming, out of the first conductive film, a common electrode which has an opening area that overlaps at least partially with an arbitrary one of the plurality of lines and also forming, out of the second conductive film, an auxiliary line which runs along the arbitrary one of the lines.

8. The method of claim 7, wherein the step (b) includes the step (b1) of forming a pixel electrode on the substrate, and
the step (e) includes the step (e1) of forming the common electrode so that the common electrode overlaps with the pixel electrode with the protective layer interposed between them.

9. The method of claim 7, further comprising the steps of:
(f) forming an insulating layer over the auxiliary line, and
(g) forming a pixel electrode which overlaps with the common electrode with the insulating layer interposed between them.

10. The semiconductor device of claim 6, wherein the oxide semiconductor layer is a crystalline In—Ga—Zn—O based semiconductor layer.

11. The method of claim 7, wherein the semiconductor layer is an oxide semiconductor.

12. The method of claim 11, wherein the oxide semiconductor layer includes In, Ga and Zn.

13. The method of claim 12, wherein the oxide semiconductor layer is a crystalline In—Ga—Zn—O based semiconductor layer.
